(19) United States
(12) Patent Application Publication
(10) Pub. No.: US 2026/0188408 A1
(43) Pub. Date: Jul. 2, 2026

(54) ADAPTIVE SLEW RATE CONTROL ACCORDING TO PROCESS AND TEMPERATURE

(71) Applicant: Micron Technology, Inc., Boise, ID (US)

(72) Inventors: Seungwook Oh, Meridian, ID (US); Ki-Jun Nam, Allen, TX (US)

(21) Appl. No.: 19/387,108

(22) Filed: Nov. 12, 2025

Related U.S. Application Data
(60) Provisional application No. 63/740,413, filed on Dec. 31, 2024.

(51) Int. Cl. G11C 29/12; G11C 29/46

(52) U.S. Cl. CPC G11C 29/12015; G11C 29/1201; G11C 29/46

(57) ABSTRACT

Slew rate compensation circuits are used to generate slew rate compensations for a memory device according to variations in process and temperature. The slew rate compensation circuits include a process/temperature detecting circuit to monitor the process and temperature of the memory device and generate a compensation signal for updating the slew rate control signal. The slew rate compensation circuits also include a slew rate update locking control circuit to control the timing of the compensation signal so that the slew rate control signal is not updated during DQ/DQS output period. The slew rate compensation circuits include a logic block to generate a compensated slew rate control signal. Accordingly, the slew rate of the memory device is adaptively controlled according to process and temperature, and the slew rate variations due to the variations of the operational properties (e.g., temperature, process) is reduced.

### CROSS-REFERENCE TO RELATED APPLICATION

This application claims priority to U.S. Provisional Application No. 63/740,413, filed Dec. 31, 2024, which is hereby incorporated by reference in its entirety.

### BACKGROUND

### Field of the Invention

Embodiments of the present disclosure relate generally to the field of semiconductor memory devices. More specifically, embodiments of the present disclosure relate to slew rate control in a memory device.

### Description of the Related Art

A semiconductor device, such as a microcomputer, memory, gate array, among others, may receive data that is to be written into a memory cell or read from a memory cell. When data is being received by the semiconductor device, the semiconductor device may initially receive the data (e.g., low voltage or high voltage) in an output buffer, and an output data signal (e.g., DQ/DQS) is generated to transmit the data. To ensure that the output data signal produced at the output buffer is read accurately by a corresponding memory component, a slew rate, which indicates how fast the output data signal can transition between different voltages (e.g., between the low voltage and the high voltage), is used to generate the output data signal. The slew rate may be defined as a change in voltage per unit of time (e.g., V/s). The slew rate may be determined for the memory component based on certain properties associated with the operation of the memory component, such as temperature, manufacturing process, noise, and the like. Accordingly, variations in the operational properties (e.g., temperature, process) of the memory component may affect the slew rate, which may affect the output signal and cause undesirable effects, such as data bus ringing, voltage undershoots, voltage overshoots, and the like. However, it may be difficult to control the slew rate corresponding to variations of the operational parameters (e.g., temperature, process).

### BRIEF DESCRIPTION OF THE DRAWINGS

Various aspects of this disclosure may be better understood upon reading the following detailed description and upon reference to the drawings in which:

FIG. 1 is a simplified block diagram illustrating certain features of a memory device, according to an embodiment of the present disclosure;

FIG. 2 is a block diagram illustrating an embodiment of slew rate compensation circuits of the memory device of FIG. 1, according to an embodiment of the present disclosure;

FIG. 3 is a block diagram illustrating an embodiment of a slew rate update locking control circuit used in the slew rate compensation circuits of FIG. 2, according to an embodiment of the present disclosure;

FIG. 4 is a timing diagram for generating a locked compensation signal using the slew rate update locking control circuit of FIG. 3, according to an embodiment of the present disclosure;

FIG. 5A is a schematic diagram illustrating an embodiment of the slew rate control circuit of the memory device of FIG. 1, according to an embodiment of the present disclosure;

FIG. 5B is a schematic diagram illustrating an embodiment of a capacitor used in the slew rate control circuit of FIG. 5A, according to an embodiment of the present disclosure;

FIG. 6 is a diagram illustrating the variations of the slew rate with respect to temperature and process, according to an embodiment of the present disclosure; and

FIG. 7 is a flow diagram of a method for generating a compensated slew rate control signal, according to an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As mentioned above, variations in the operational properties (e.g., temperature, process) of a memory device may affect the slew rate, which may affect the output data signal and cause undesirable effects. Accordingly, it is desirable to control the slew rate corresponding to variations of the operational parameters (e.g., temperature, process) of the memory device. The slew rate of a voltage signal may be controlled by using delays to stagger the connection of a voltage source (e.g., VDDQ) to an output buffer. For instance, the voltage source may be coupled to the output buffer via an output driver, which may include a number of driver units that may be turned on or off based on the delays to control the slew rate of the voltage signal provided to the output buffer. For example, there may be a number of parallel-coupled driver units having predefined impedance values (e.g., 120 Ω, 240Ω) to connect the voltage source to the output buffer, and each of the driver units may be turned on at a certain delay time and for a certain period of time based on the delays to adjust the slew rate of the voltage signal. A slew rate control circuit may be used to generate the delays based on a control signal (e.g., tmfzSlew<3:0>) generated by a set of slew rate control testmode fuses (e.g., tmfz).

Generally, different memory devices specify slew rates for expected voltage signals to ensure that a clock of the memory device accurately produces the voltage signal that corresponds to output data. The specification may thus provide minimum or maximum limits on the voltage slew rates under certain conditions (e.g., operating conditions, output loadings, data patterns, noise profiles). As such, the specification for the memory device may ensure that the slew rate will be at least the given minimum for driving the memory device but at most the given maximum for limiting high frequency noise, which may cause undesirable effects, such as data bus ringing, voltage undershoots, voltage overshoots, and the like. However, the variations of the operational properties (e.g., temperature, process) may affect the slew rate and cause increased slew rate variations. Accordingly, it is desired to reduce the slew rate variations.

The disclosure herein provides systems and methods for adaptively controlling a slew rate of a memory device according to real-time process and temperature of the memory device. The process and temperature of the memory device are monitored by a process/temperature detecting circuit. The process/temperature detecting circuit may generate a compensation signal (e.g., Tcomp_pre) for compensating the variations in process and temperature. The compensation signal may be used to update the slew rate control signal (e.g., tmfzSlew<3:0>). To prevent metastability, a slew rate update locking control circuit is used to control the timing of the compensation signal so that the slew rate control signal may not be updated during DQ/DQS output time period. The locked compensation signal (e.g., Tcomp) from the slew rate update locking control circuit is combined with the slew rate control signal to generate a compensated slew rate control signal (e.g., tmfzSlew_Tcomp<3:0>). The compensated slew rate control signal may be used to control the slew rate. Accordingly, the slew rate of a memory device may be adaptively controlled according to process and temperature, and the slew rate variations due to the variations of the operational properties (e.g., temperature, process) may be reduced.

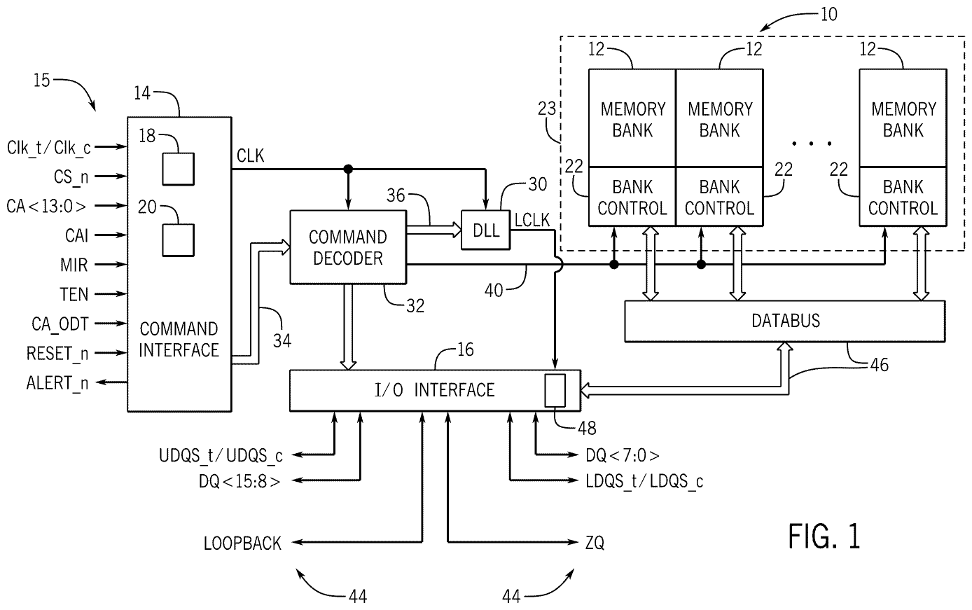

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type five synchronous dynamic random access memory (DDR5 SDRAM) device. Various features of DDR5 SDRAM allow for reduced power consumption, more bandwidth and more storage capacity compared to prior generations of DDR SDRAM.

The memory device 10, may include a number of memory banks 12. The memory banks 12 may be DDR5 SDRAM memory banks, for instance. The memory banks 12 may be provided on one or more chips (e.g., SDRAM chips) that are arranged on dual inline memory modules (DIMMS). Each DIMM may include a number of SDRAM memory chips (e.g., ×8 or ×16 memory chips), as will be appreciated. Each SDRAM memory chip may include one or more memory banks 12. The memory device 10 represents a portion of a single memory chip (e.g., SDRAM chip) having a number of memory banks 12. For DDR5, the memory banks 12 may be further arranged to form bank groups. For instance, for an 8 gigabit (Gb) DDR5 SDRAM, the memory chip may include 16 memory banks 12, arranged into 8 bank groups, each bank group including 2 memory banks. For a 16 GB DDR5 SDRAM, the memory chip may include 32 memory banks 12, arranged into 8 bank groups, each bank group including 4 memory banks, for instance. Various other configurations, organization and sizes of the memory banks 12 on the memory device 10 may be utilized depending on the application and design of the overall system.

The memory device 10 may include a command interface 14 and an input/output (I/O) interface 16 configured to exchange (e.g., receive and transmit) signals with external devices. The command interface 14 is configured to provide a number of signals (e.g., signals 15) from an external device (not shown), such as a processor or controller. The processor or controller may provide various signals 15 to the memory device 10 to facilitate the transmission and receipt of data to be written to or read from the memory device 10.

As will be appreciated, the command interface 14 may include a number of circuits, such as a clock input circuit 18 and a command address input circuit 20, for instance, to ensure proper handling of the signals 15. The command interface 14 may receive one or more clock signals from an external device. Generally, double data rate (DDR) memory utilizes a differential pair of system clock signals, referred to herein as the true clock signal (Clk_t) and the complementary clock signal (Clk_c). The positive clock edge for DDR refers to the point where the rising true clock signal Clk_t crosses the falling complementary clock signal Clk_c, while the negative clock edge indicates that transition of the falling true clock signal Clk_t and the rising of the complementary clock signal Clk_c. Commands (e.g., read command, write command, etc.) are typically entered on the positive edges of the clock signal and data is transmitted or received on both the positive and negative clock edges.

The clock input circuit 18 receives the true clock signal (Clk_t) and the complementary clock signal (Clk_c) and generates an internal clock signal CLK. The internal clock signal CLK is supplied to an internal clock generator 30, such as a delay locked loop (DLL) circuit. The internal clock generator 30 generates a phase controlled internal clock signal LCLK based on the received internal clock signal CLK. The phase controlled internal clock signal LCLK is supplied to the I/O interface 16, for instance, and is used as a timing signal for determining an output timing of read data.

The internal clock signal CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For instance, the command decoder 32 may provide command signals to the internal clock generator 30 over the bus 36 to coordinate generation of the phase controlled internal clock signal LCLK. The phase controlled internal clock signal LCLK may be used to clock data through the I/O interface 16, for instance.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes a bank control block 22 which provides the necessary decoding (e.g., row decoder and column decoder), as well as other features, such as timing control and data control, to facilitate the execution of commands to and from the memory banks 12. Collectively, the memory banks 12 and the bank control blocks 22 may be referred to as a memory array 23.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20 which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands.

In addition, the command interface 14 may be configured to receive a number of other command signals. For instance, a command/address on die termination (CA_ODT) signal may be provided to facilitate proper impedance matching within the command interface 14. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the I/O interface 16. More specifically, the data may be sent to or retrieved from the memory banks 12 over the data bus 46, which includes a plurality of bi-directional data buses. Data I/O signals, generally referred to as DQ signals, are generally transmitted and received in one or more bi-directional data buses. For certain memory devices, such as a DDR5 SDRAM memory device, the I/O signals may be divided into upper and lower bytes. For instance, for an ×16 memory device, the I/O signals may be divided into upper and lower I/O signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the data strobe (DQS) signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance.

An impedance (ZQ) calibration signal may also be provided to the memory device 10 through the I/O interface 16. The ZQ calibration signal may be used to tune output drivers and on die termination (ODT) values of external pins (e.g., DQ pad, CA pad) by adjusting pull-up and pull-down driver units of the memory device 10 across changes in process, voltage and temperature (PVT) values. Because PVT characteristics may impact the driver unit values, resistances of the driver units may fluctuate from predefined values (e.g., 240Ω). The driver units are made tunable, and the ZQ calibration signal may be used to calibrate the resistances of the driver units to the predefined values by using an external resistor having precise resistance. This process is called ZQ calibration. As will be appreciated, a precision resistor is generally coupled between a ZQ pad on the memory device 10 and GND/VSS external to the memory device 10. This precision resistor acts as a reference for the ZQ calibration.

In addition, a loopback signal (LOOPBACK) may be provided to the memory device 10 through the I/O interface 16. The loopback signal may be used during a test or debugging phase to set the memory device 10 into a mode wherein signals are looped back through the memory device 10 through the same pin. For instance, the loopback signal may be used to set the memory device 10 to test the data output of the memory device 10. Loopback may include both a data and a strobe or possibly just a data pin. This is generally intended to be used to monitor the data captured by the memory device 10 at the I/O interface 16.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), process monitoring circuit (for monitoring processes of the memory device 10), etc., may also be incorporated into the memory system 10. Accordingly, it should be understood that the block diagram of FIG. 1 is only provided to highlight certain functional features of the memory device 10 to aid in the subsequent detailed description.

In some embodiments, the memory device 10 may be disposed in (physically integrated into or otherwise connected to) a host device or otherwise coupled to a host device. The host device may include any one of a desktop computer, laptop computer, pager, cellular phone, personal organizer, portable audio player, control circuit, camera, etc. The host device may also be a network node, such as a router, a server, or a client (e.g., one of the previously-described types of computers). The host device may be some other sort of electronic device, such as a copier, a scanner, a printer, a game console, a television, a set-top video distribution or recording system, a cable box, a personal digital media player, a factory automation system, an automotive computer system, or a medical device. (The terms used to describe these various examples of systems, like many of the other terms used herein, may share some referents and, as such, should not be construed narrowly in virtue of the other items listed.)

The host device may, thus, be a processor-based device, which may include a processor, such as a microprocessor, which controls the processing of system functions and requests in the host. Further, any host processor may comprise a plurality of processors that share system control. The host processor may be coupled directly or indirectly to additional system elements of the host, such that the host processor controls the operation of the host by executing instructions that may be stored within the host or external to the host.

As discussed above, data may be written to and read from the memory device 10, for example, by the host whereby the memory device 10 operates as volatile memory, such as Double Data Rate DRAM (e.g., DDR5 SDRAM). The host may, in some embodiments, also include separate non-volatile memory, such as read-only memory (ROM), PC-RAM, silicon-oxide-nitride-oxide-silicon (SONOS) memory, metal-oxide-nitride-oxide-silicon (MONOS) memory, polysilicon floating gate based memory, and/or other types of flash memory of various architectures (e.g., NAND memory, NOR memory, etc.) as well as other types of memory devices (e.g., storage), such as solid state drives (SSD's), MultimediaMediaCards (MMC's), SecureDigital (SD) cards, CompactFlash (CF) cards, or any other suitable device. Further, it should be appreciated that the host may include one or more external interfaces, such as Universal Serial Bus (USB), Peripheral Component Interconnect (PCI), PCI Express (PCI-E), Small Computer System Interface (SCSI), IEEE 1394 (Firewire), or any other suitable interface as well as one or more input devices to allow a user to input data into the host, for example, buttons, switching elements, a keyboard, a light pen, a stylus, a mouse, and/or a voice recognition system, for instance. The host may optionally also include an output device, such as a display coupled to the processor and a network interface device, such as a Network Interface Card (NIC), for interfacing with a network, such as the Internet. As will be appreciated, the host may include many other components, depending on the application of the host.

The host may operate to transfer data to the memory device 10 for storage and may read data from the memory device 10 to perform various operations at the host. In some embodiments, the I/O interface 16 may include a slew rate control circuit 48 that operates to adjust the slew rate for DQ/DQS signal. For instance, the slew rate of a voltage signal may be controlled by using delays to stagger the connection of a voltage source (e.g., VDDQ) to an output buffer. The voltage source may be coupled to the output buffer via an output driver, which may include a number of driver units that may be turned on or off based on the delays to control the slew rate of the voltage signal provided to the output buffer. For example, there may be a number of parallel-coupled driver units having predefined impedance values (e.g., 120 Ω, 240Ω) to connect the voltage source to the output buffer, and each of the driver units may be turned on at a certain delay time and for a certain period of time based on the delays to adjust the slew rate. The slew rate control circuit 48 may be used to generate the delays based on a control signal (e.g., tmfzSlew<3:0>) generated by a set of slew rate control testmode fuses (e.g., tmfz).

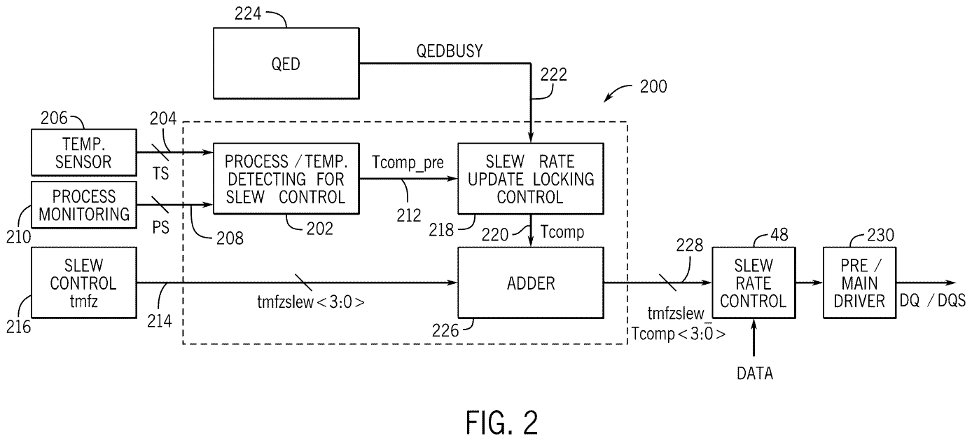

FIG. 2 is a block diagram illustrating an embodiment of slew rate compensation circuits 200 that may be used to generate slew rate compensations for the memory device 10 according to variations in process and temperature of the memory device 10. The slew rate compensation circuits 200 may be located in the I/O interface 16. The slew rate compensation circuits 200 may include a process/temperature detecting circuit 202, which may be used to monitor the process and temperature of the memory device 10. For instance, the process/temperature detecting circuit 202 may receive a temperature signal 204 (e.g., TS) from a temperature monitoring device 206 (e.g., a temperature sensor). The temperature signal 204 may include information of the real-time temperature condition (e.g., <8° C., <40° C., <72° C.) of the memory device 10. The process/temperature detecting circuit 202 may also receive a process signal 208 (e.g., PS) from a process monitoring device 210. The process signal 208 may include information of the real-time process condition of the memory device 10, such as Slow-Typical (ST), Fast-Fast (FF), Typical-Typical (TT), Fast-Typical (FT), Joint-Fast-Slow (JFS), Joint-Slow-Fast (JSF), Typical-Fast (TF), Joint-Slow-Slow (JSS), and the like. When a combination of the temperature condition and process condition satisfies a predefined condition, the process/temperature detecting circuit 202 may enable a corresponding compensation signal 212 (e.g., Tcomp_pre). Table 1 illustrates an embodiment of mappings of temperature conditions, process conditions, and corresponding compensation signals.

TABLE 1

| | Temp. condition | Output control |
|---|---|---|
| Process condition | TS<9:5> | signal (Tcomp_pre) |

| | | | | |
|---|---|---|---|---|
| PS<2:0> | ST | <8° | C. | Enabled under 8° C. |
| | TS | | | |
| | TT | | | |
| | FT | <40° | C. | Enabled under 40° C. |
| | JFS | | | |
| | JSF | | | |
| | JFF | <72° | C. | Enabled under 72° C. |

| | | |
|---|---|---|
| TF | | |
| JSS | None | Not enabled |

For example, the process signal 208 may include 3 digits (e.g., PS<2:0>) and may be used to indicate various process conditions (e.g., ST, TS, TT, FT, JFS, JFF, TF, JSS), and a portion of the temperature signal 204 (e.g., TS<9:5>) may include information of the temperature conditions. As illustrated in Table 1, a corresponding output control signal (e.g., Tcomp_pre) may be enabled when a process condition and a temperature condition are satisfied. For example, when the process condition corresponds to “ST” and the temperature condition corresponds to “<8° C.”, a corresponding output control signal defined for under 8° C. may be enabled. The process conditions and temperature conditions may be determined based on the characteristics of the memory device 10.

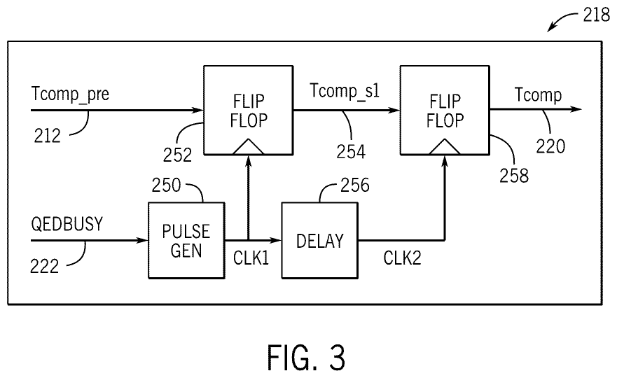

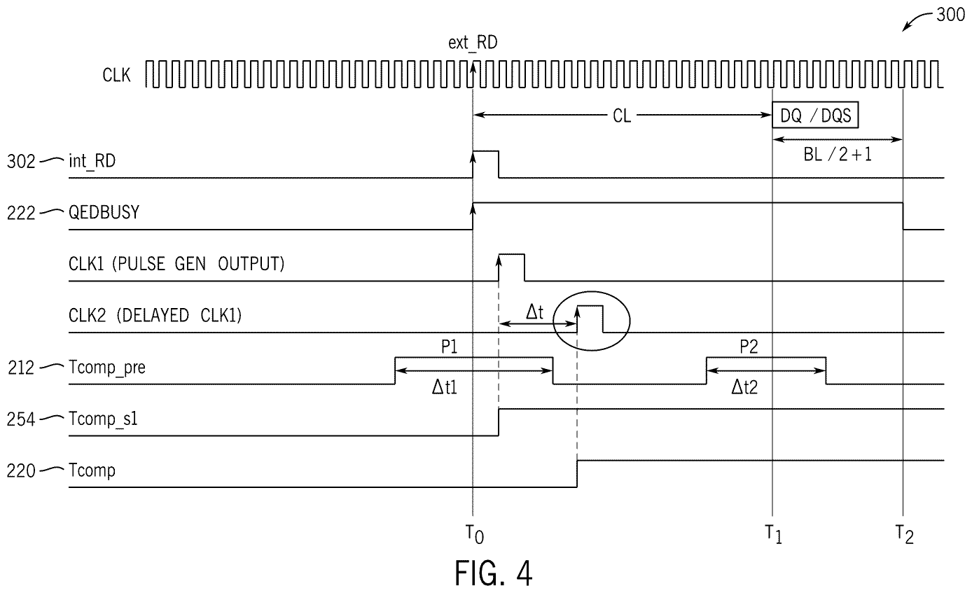

The compensation signal 212 may include compensations for slew rate variations due to the variations of the process and temperature, and it may be used with a slew rate control signal (e.g., tmfzSlew<3:0>) 214, which is generated by a set of slew rate control testmode fuses 216, to generate a compensated slew rate control signal 228 (e.g., tmfzSlew_Tcomp<3:0>). To avoid updating the compensated slew rate control signal 228 during DQ/DQS output period, which may cause meta-stability, the slew rate compensation circuits 200 may include a slew rate update locking control circuit 218 to control the timing of the compensation signal 212 so that the slew rate control signal 214 may not be updated during DQ/DQS output period. The slew rate update locking control circuit 218 may generate a locked compensation signal 220 (e.g., Tcomp) having defined timing by using a DQ enable delay (QED) busy signal 222 received from a QED shifter 224, as illustrated in FIG. 3. The QED shifter 224 may include multiple stages (e.g., flip-flops) to shift commands that have an output component (e.g., read and/or on-die termination (RTT) commands) for a specified latency for the memory device 10. For example, the specified latency may be the column address strobe (CAS) latency (CL), which is the delay time between a READ command is received and the time that the corresponding data is available for the READ command. The CL may be specified for the memory device 10 from the host device (e.g., via a mode register) or calculated using the DLL circuitry of the memory device 10. The QED busy signal 222 may be enabled when the READ command is received and last after the data is read, as illustrated in FIG. 4.

As illustrated in FIG. 2, the slew rate compensation circuits 200 may include a logic block/circuit 226 that may be used to generate the compensated slew rate control signal 228 (e.g., tmfzSlew_Tcomp<3:0>). The logic block 226 may include adder/subtractor circuitry to add to or subtract from the slew rate control signal 214 (e.g., tmfzSlew<3:0>) a number (e.g., 0, 1, 2, 3 . . . ) determined based on the value of the locked compensation signal 220 to generate the compensated slew rate control signal 228. The compensated slew rate control signal 228 may be transmitted to the slew rate control circuit 48 and may be used to adjust the slew rate for DQ/DQS signal by generating corresponding delays for an output driver 230 (e.g., Pre/Main driver). For example, the output driver 230 may include pull up driver units and/or pull down driver units, and the delays may be used to control the pull up driver units and/or pull down driver units to adjust the corresponding slew rate.

FIG. 3 is a block diagram showing an embodiment of the slew rate update locking control circuit 218. The slew rate update locking control circuit 218 may include a pulse generator 250 to generate a signal CLK1 when receiving the rising edge of the QED busy signal 222. The slew rate update locking control circuit 218 may include a flip-flop 252 to receive the compensation signal 212. The flip-flop 252 may be triggered by the rising edge of the signal CLK1 and output a signal 254 (e.g., Tcomp_s1) having the same value as the value of the compensation signal 212 at the time of the rising edge of the signal CLK1. The signal 254 may maintain the value before it is updated by another rising edge of the signal CLK1 received by the flip-flop 252, as illustrated in FIG. 4. The signal CLK1 may be transmitted to a delay device 256, which may add a predefined delay Δt to the signal CLK1 to generate a signal CLK2. The signal 254 may be transmitted to a flip-flop 258. The flip-flop 258 may be triggered by the rising edge of the signal CLK2 and output the locked compensation signal 220 having the same value as the value of the signal 254 at the time of the rising edge of the signal CLK2. The locked compensation signal 220 may maintain the value before it is updated by another rising edge of the signal CLK2 received by the flip-flop 258, as illustrated in FIG. 4.

FIG. 4 is a timing diagram 300 for generating the locked compensation signal 220. At time TO, an external READ command (e.g., ext_RD) is received by the memory device 10 and an internal READ signal 302 (e.g., int_RD) is generated. At time T1, data for the READ command may be available to read, and the data (e.g., DQ/DQS) may be read in a read period (e.g., the burst length (BL) divided by two since the data may be read from memory on both falling edges and rising edges of the clock signal CLK). Accordingly, the time period between time TO and time T1 is the column address strobe latency CL. In the illustrated embodiment of FIG. 4, a buffer (e.g., 1 clock period) may be added to the end of the read period to allow parameters to settle between operations. Accordingly, the total read time is BL/2+1, and the READ operation is completed at time T2. The QED busy signal 222 may be enabled at TO, at the rising edge of the internal READ signal 302, and may last until time T2, when the READ operation is completed.

As described above in the paragraph regarding FIG. 3, the signal CLK1 may be generated using the rising edge of the QED busy signal 222. The signal CLK2 may then be generated using the rising edge of the signal CLK1 with the predefined delay Δt. As illustrated in FIG. 4, the signal 254 may be updated at the rising edge of the signal CLK1 and may have the same value as the value of the compensation signal 212 at the time of the rising edge of the signal CLK1. The locked compensation signal 220 may be updated at the rising edge of the signal CLK2 and may have the same value as the value of the signal 254 at the time of the rising edge of the signal CLK2. The value of the predefined delay Δt is designed so that the locked compensation signal 220 may not be updated during DQ output period (e.g., between T1 and T2), which may cause meta-stability. Moreover, the locked compensation signal 220 may not be updated more than once during the CL time period. For example, the compensation signal 212 may include a first pulse P1 (e.g., with logic high during At1), and the first pulse P1 may be used to update the signal 254 since the rising edge of the signal CLK1 occurs during the time period of the first pulse P1. The updated signal 254 may then be used to update the locked compensation signal 220. The compensation signal 212 may include a second pulse P2 (e.g., with logic high during At2). Since no rising edge of the signal CLK1 occurs during the time period of the second pulse P2, the signal 254 may not be updated corresponding to the second pulse P2. Accordingly, the locked compensation signal 220 may not be updated corresponding to the second pulse P2 since the signal 254 is not updated. In some embodiments, the predefined delay Δt may be determined based on characteristics of the memory device 10, while in other embodiments, the predefined delay Δt may have a predetermined value (e.g., 1-3 ns).

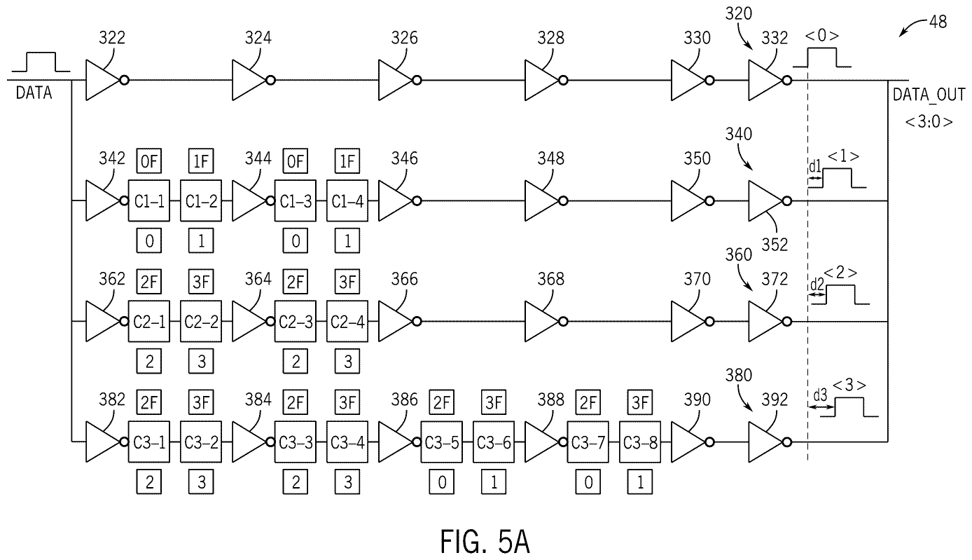

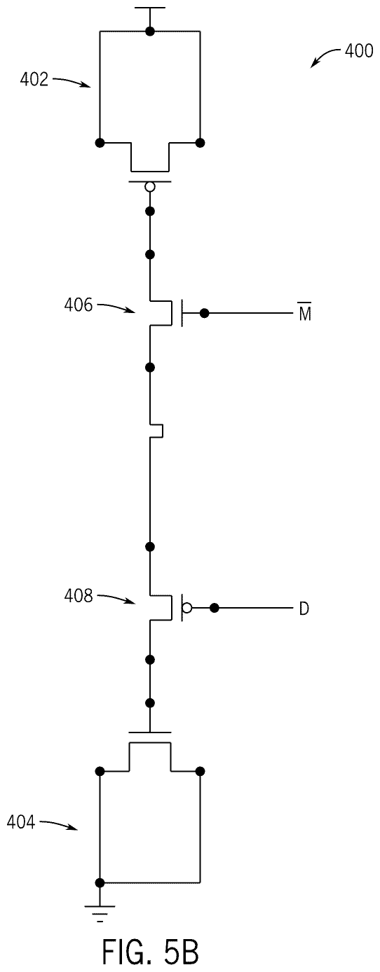

FIG. 5A illustrates an embodiment of the slew rate control circuit 48. The slew rate control circuit 48 may be used to generate a set of signals with relative delays for the output data. The set of signals may be coupled to respective driver units of the output driver 230 to stagger the connection of a voltage source (e.g., VDDQ) to an output buffer to adjust the slew rate of the output data signal (e.g., DQ/DQS). In the illustrated embodiment of FIG. 5A, the slew rate control circuit 48 may include four branches 320, 340, 360, and 380 to generate four signals (e.g., represented by signals <0>, <1>, <2>, and <3>), respectively. For example, the signal <0> may be coupled to a first driver unit of the output driver 230, which has a first predefined impedance value (e.g., 240Ω); the signal <1> may be coupled to a second driver unit of the output driver 230, which has a second predefined impedance value; the signal <2> may be coupled to a third driver unit of the output driver 230, which has a third predefined impedance value; and the signal <3> may be coupled to a fourth driver unit of the output driver 230, which has a fourth predefined impedance value. In some embodiments, the second driver unit, the third driver unit, and the fourth driver unit may have the same predefined impedance value (e.g., 120Ω). Accordingly, the four driver units of the output driver 230 may be turned on and turned off by the corresponding signals to adjust the slew rate of the output data signal DQ/DQS. The signal <0> may be used as the base line, and relative delays (e.g., d1, d2, d3) may be generated between the signals <1>, <2>, <3> and the signal <0> based on the compensated slew rate control signal 228. Accordingly, the slew rate of the output data signal DQ/DQS may be adjusted based on the compensated slew rate control signal 228.

Each of the four branches of the slew rate control circuit 48 may include an even number (e.g., 6) of inverters connected in series, and capacitors may be coupled to some of the inverters to adjust the delay of the signal. For example, the branch 320 may include inverters 322, 324, 326, 328, 330, and 332 connected in series, and the generated signal <0> may be used as the base line. The branch 340 may include inverters 342, 344, 346, 348, 350, and 352 connected in series, and the generated signal <1> may be delayed by d1 relative to the signal <0>. The delay d1 may be generated by using capacitors C₁₋₁, C₁₋₂, C₁₋₃, and C₁₋₄, which may be controlled by the first two digits (e.g., digit [0], digit [1]) of the compensated slew rate control signal 228 (e.g., tmfzSlew_Tcomp<3:0>). The capacitor C₁₋₁ may be coupled to the inverter 342 and controlled by the digit [0] and the flipped digit [0] (e.g., 0F) of the compensated slew rate control signal 228. The capacitor C₁₋₂ may be coupled to the inverter 342 and controlled by the digit [1] and the flipped digit [1] (e.g., 1F) of the compensated slew rate control signal 228. The capacitor C₁₋₃ may be coupled to the inverter 344 and controlled by the digit [0] and the flipped digit [0] (e.g., 0F) of the compensated slew rate control signal 228. The capacitor C₁₋₄ may be coupled to the inverter 344 and controlled by the digit [1] and the flipped digit [1] (e.g., 1F) of the compensated slew rate control signal 228. The values of the capacitors may be the same or different. When one of the capacitors is enabled, a corresponding delay may be added to the signal <1>, and the total delay of the signal <1> relative to the signal <0> is d1.

The branch 360 may include inverters 362, 364, 366, 368, 370, and 372 connected in series, and the generated signal <2> may be delayed by d2 relative to the signal <0>. The delay d2 may be generated by using capacitors C₂₋₁, C₂₋₂, C₂₋₃, and C₂₋₄, which may be controlled by the next two digits (e.g., digit [2], digit [3]) of the compensated slew rate control signal 228 (e.g., tmfzSlew_Tcomp<3:0>). The capacitor C₂₋₁ may be coupled to the inverter 362 and controlled by the digit [2] and the flipped digit [2] (e.g., 2F) of the compensated slew rate control signal 228. The capacitor C₂₋₂ may be coupled to the inverter 362 and controlled by the digit [3] and the flipped digit [3] (e.g., 3F) of the compensated slew rate control signal 228. The capacitor C₂₋₃ may be coupled to the inverter 364 and controlled by the digit [2] and the flipped digit [2] (e.g., 2F) of the compensated slew rate control signal 228. The capacitor C₂₋₄ may be coupled to the inverter 364 and controlled by the digit [3] and the flipped digit [3] (e.g., 3F) of the compensated slew rate control signal 228. The values of the capacitors may be the same or different. When one of the capacitors is enabled, a corresponding delay may be added to the signal <2>, and the total delay of the signal <2> relative to the signal <0> is d2.

The branch 380 may include inverters 382, 384, 386, 388, 390, and 392 connected in series, and the generated signal <3> may be delayed by d3 relative to the signal <0>. The delay d3 may be generated by using capacitors C₃₋₁, C₃₋₂, C₃₋₃, C₃₋₄, C₃₋₅, C₃₋₆, C₃₋₇, and C₃₋₈, which may be controlled by all digits (e.g., digit [0], digit [1], digit [2], digit [3]) of the compensated slew rate control signal 228 (e.g., tmfzSlew_Tcomp<3:0>). The capacitor C₃₋₁ may be coupled to the inverter 382 and controlled by the digit [2] and the flipped digit [2] (e.g., 2F) of the compensated slew rate control signal 228. The capacitor C₃₋₂ may be coupled to the inverter 382 and controlled by the digit [3] and the flipped digit [3] (e.g., 3F) of the compensated slew rate control signal 228. The capacitor C₃₋₃ may be coupled to the inverter 384 and controlled by the digit [2] and the flipped digit [2] (e.g., 2F) of the compensated slew rate control signal 228. The capacitor C₃₋₄ may be coupled to the inverter 384 and controlled by the digit [3] and the flipped digit [3] (e.g., 3F) of the compensated slew rate control signal 228. The capacitor C₃₋₅ may be coupled to the inverter 386 and controlled by the digit [0] and the flipped digit [2] (e.g., 2F) of the compensated slew rate control signal 228. The capacitor C₃₋₆ may be coupled to the inverter 386 and controlled by the digit [1] and the flipped digit [3] (e.g., 3F) of the compensated slew rate control signal 228. The capacitor C₃₋₇ may be coupled to the inverter 388 and controlled by the digit [0] and the flipped digit [2] (e.g., 2F) of the compensated slew rate control signal 228. The capacitor C₃₋₈ may be coupled to the inverter 388 and controlled by the digit [1] and the flipped digit [3] (e.g., 3F) of the compensated slew rate control signal 228.

The values of the capacitors may be the same or different. When one of the capacitors is enabled, a corresponding delay may be added to the signal <3>, and the total delay of the signal <3> relative to the signal <0> is d3. The signals <0>, <1>, <2>, and <3> may be coupled to corresponding driver units of the output driver 230 to adjust the slew rate of the output data signal DQ/DQS. Since the delays (e.g., d1, d2, d3) of the signals are controlled by the compensated slew rate control signal 228, the slew rate may be adaptively adjusted according to the real-time variations in process and temperature. For example, large delays of the signals may cause reduced slew rate while small delays of the signals may cause increased slew rate.

It should be noted that FIG. 5A only illustrates an embodiment of the slew rate control circuit 48. Different numbers of inverters and capacitors, as well as different combinations of digits (e.g., 0 and 0F, 1 and 1F, 2 and 2F, 3 and 3F, 0 and 2F, 1 and 3F are used in FIG. 5A) of the compensated slew rate control signal 228 may be used in other embodiments to control the delays of the signals. The values of the capacitors may also be determined to have improved adjustment of the slew rate control. In some embodiments, capacitors with large capacitance and capacitors with small capacitance may be used together in the slew rate control circuit 48 to obtain improved results. For example, the capacitors used in the branch 340 may have small capacitance, the capacitors used in the branch 360 may have large capacitance, and the capacitors used in the branch 380 may have both large capacitance and small capacitance (e.g., some of the capacitors have small capacitance while the others have large capacitance).

The capacitors used in the slew rate control circuit 48 may be any type of capacitor. In some embodiments, metal-oxide-semiconductor (MOS) capacitors may be used in the slew rate control circuit 48. FIG. 5B shows an embodiment of a MOS capacitor 400 that may be used in the slew rate control circuit 48. The MOS capacitor 400 may include a PMOS (p-channel metal-oxide semiconductor) capacitor 402 and an NMOS (n-channel metal-oxide semiconductor) capacitor 404. The PMOS capacitor 402 may be coupled to the NMOS capacitor 404 via an NMOS transistor 406 and a PMOS transistor 408. The gate of the PMOS transistor 408 may be controlled by a digit D (e.g., D=0, 1, 2, 3) of the compensated slew rate control signal 228 (e.g., tmfzSlew_Tcomp<3:0>), while the gate of the NMOS transistor 406 may be controlled by a flipped digit M (e.g., M=0, 1, 2, 3) of the compensated slew rate control signal 228. The body of the NMOS capacitor 404 may be coupled to a voltage source (e.g., ground). The capacitance of the MOS capacitor 400 may change depending on the voltages applied to the gates of the PMOS capacitor 402 and the NMOS capacitor 404, which are controlled by the digit D and the flipped digit M of the compensated slew rate control signal 228. For example, when D=0 and M=0, the capacitance of the MOS capacitor 400 may be controlled by the digit [0] and the flipped digit [0] (e.g., 0F) of the compensated slew rate control signal 228.

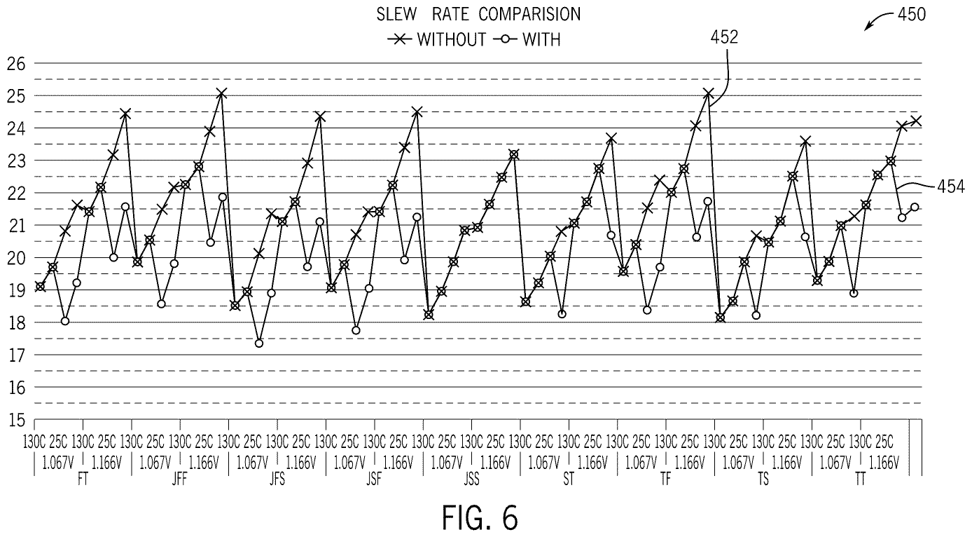

FIG. 6 is a diagram 450 illustrating the variations of the slew rate with respect to temperature and process. In FIG. 6, a curve 452 shows variations of the slew rate when the slew rate compensation circuits 200 are not used to generate slew rate compensations according to variations in process and temperature. A curve 454 shows variations of the slew rate when the slew rate compensation circuits 200 are used to generate slew rate compensations according to variations in process and temperature. As illustrated in FIG. 6, the variations of the slew rate is reduced when the slew rate compensation circuits 200 are used to generate slew rate compensations according to variations in process and temperature.

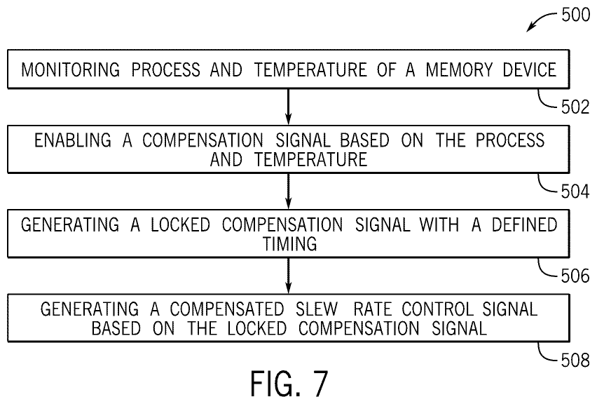

FIG. 7 is a flow diagram of a method 500 for generating the compensated slew rate control signal 228. At block 502, the process and temperature of the memory device 10 may be monitored by the process/temperature detecting circuit 202 using the temperature monitoring device 206 and the process monitoring device 210. At block 504, when a combination of the temperature condition and process condition satisfies a predefined condition, the process/temperature detecting circuit 202 may enable the corresponding compensation signal 212 (e.g., Tcomp_pre). At block 506, the slew rate update locking control circuit 218 may be used to generate the locked compensation signal 220 (e.g., Tcomp) based on the compensation signal 212 and a defined timing so that the compensated slew rate control signal 228 may not be updated during DQ output period. At block 508, the logic block 226 may be used to generate the compensated slew rate control signal 228 (e.g., tmfzSlew_Tcomp<3:0>) based on the locked compensation signal 220 (e.g., Tcomp) and the slew rate control signal 214.

Accordingly, the technical effects of the present disclosure include methods and systems for adaptively controlling a slew rate of a memory device according to process and temperature of the memory device. The real-time process and temperature of the memory device are monitored by a process/temperature detecting circuit. The process/temperature detecting circuit may generate a compensation signal (e.g., Tcomp_pre) for compensating the variations in process and temperature. The compensation signal may be used to update the slew rate control signal (e.g., tmfzSlew<3:0>). A slew rate update locking control circuit is used to control the timing of the compensation signal so that the slew rate control signal may not be updated during DQ/DQS output time period. The locked compensation signal (e.g., Tcomp) from the slew rate update locking control circuit is combined with the slew rate control signal to generate a compensated slew rate control signal (e.g., tmfzSlew_Tcomp<3:0>). The compensated slew rate control signal may be used to control the slew rate. Accordingly, the slew rate of a memory device may be adaptively controlled according to real-time process and temperature, and the slew rate variations due to the variations of the operational properties (e.g., temperature, process) may be reduced.

In the illustrated embodiments above, the memory devices and systems are primarily described in the context of devices incorporating DRAM storage media. Memory devices configured in accordance with other embodiments of the present technology, however, may include other types of memory devices and systems incorporating other types of storage media, including PCM, SRAM, FRAM, RRAM, MRAM, read only memory (ROM), erasable programmable ROM (EPROM), electrically erasable programmable ROM (EEROM), ferroelectric, magnetoresistive, and other storage media, including non-volatile, flash (e.g., NAND and/or NOR) storage media.

It should be understood that logically-equivalent circuitry may be used to implement the systems and methods described above. For example, a logical XOR gate may be replaced via a logically-equivalent combination of NOT gates, AND gates, Inverse NOT gates, OR gates, NAND gates, NOR gates, or the like.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

What is claimed is:

1. Slew rate compensation circuits, comprising:
a detecting circuit configured to enable a compensation signal based on a temperature condition and a process condition of a memory device;
a locking circuit configured to generate a locked compensation signal based on the compensation signal and a predefined delay; and
a logic block to generate a compensated slew rate control signal based on the locked compensation signal.

2. The slew rate compensation circuits of claim 1, wherein the detecting circuit is configured to:
detect the temperature condition in real time via a temperature sensor; and
detect the process condition in real time via a process monitoring device.

3. The slew rate compensation circuits of claim 1, wherein the locking circuit comprises:
a pulse generator to generate a first clock signal; and
a delay device to generate a second clock signal using the first clock signal based on the predefined delay, wherein the predefined delay is determined such that the compensated slew rate control signal is generated during a particular time period.

4. The slew rate compensation circuits of claim 3, wherein the pulse generator is configured to generate the first clock signal based on a DQ enable delay (QED) busy signal generated when a READ command is received by the memory device.

5. The slew rate compensation circuits of claim 4, wherein the particular time period is a column address strobe (CAS) latency for the READ command.

6. The slew rate compensation circuits of claim 1, wherein the logic block comprises adder/subtractor circuitry to add to or subtract from a slew rate control signal a number determined based on the locked compensation signal.

7. The slew rate compensation circuits of claim 6, wherein the slew rate control signal is generated by a set of slew rate control testmode fuses.

8. The slew rate compensation circuits of claim 1, wherein the compensated slew rate control signal is used by a slew rate control circuit of the memory device to generate a set of signals with relative delays, wherein the set of signals is used to adjust a slew rate of an output data signal of the memory device.

9. The slew rate compensation circuits of claim 8, wherein the slew rate control circuit comprises one or more capacitors to generate the relative delays, and wherein the one or more capacitors comprises a metal-oxide-semiconductor (MOS) capacitor.

10. The slew rate compensation circuits of claim 9, wherein the MOS capacitor comprises a p-channel metal-oxide semiconductor capacitor (PMOS) and an n-channel metal-oxide semiconductor capacitor (NMOS).

11. A method, comprising:
monitoring a process and a temperature of a memory device;
enabling a compensation signal based on the process and the temperature;
generating a locked compensation signal with a defined timing by using the compensation signal; and
generating a compensated slew rate control signal based on the locked compensation signal.

12. The method of claim 11, wherein the defined timing is determined such that the compensated slew rate control signal is generated during a particular time period.

13. The method of claim 12, wherein the particular time period is a column address strobe (CAS) latency for a READ command received by the memory device.

14. The method of claim 11, comprising:
generating, via a slew rate control circuit, a set of signals with relative delays based on the compensated slew rate control signal, wherein the set of signals is used to adjust a slew rate of an output data signal of the memory device.

15. A device, comprising:
slew rate compensation circuits configured to:
detect a temperature condition and a process condition of the device;
enable a compensation signal based on the temperature condition and the process condition;
generate a locked compensation signal based on the compensation signal and a predefined delay; and
generate a compensated slew rate control signal based on the locked compensation signal; and
a slew rate control circuit configured to generate a set of signals with relative delays based on the compensated slew rate control signal, wherein the set of signals is used to adjust a slew rate of an output data signal of the device.

16. The device of claim 15, wherein the predefined delay is determined such that the compensated slew rate control signal is generated during a particular time period.

17. The device of claim 16, wherein the particular time period is a column address strobe (CAS) latency for a READ command received by the device.

18. The device of claim 15, wherein the slew rate compensation circuits comprise adder/subtractor circuitry to generate the compensated slew rate control signal by adding to or subtracting from a slew rate control signal a number determined based on the locked compensation signal.

19. The device of claim 15, wherein the slew rate control circuit comprises one or more capacitors to generate the relative delays, and wherein the one or more capacitors comprises a metal-oxide-semiconductor (MOS) capacitor.

20. The device of claim 19, wherein the MOS capacitor comprises a p-channel metal-oxide semiconductor capacitor (PMOS) and an n-channel metal-oxide semiconductor capacitor (NMOS).
